(19) United States
(12) Patent Application Publication
(10) Pub. No.: US 2023/0238037 A1
(43) Pub. Date: Jul. 27, 2023

(54) CONTENT ADDRESSABLE MEMORY DEVICE AND METHOD FOR DATA SEARCHING AND COMPARING THEREOF

(71) Applicant: MACRONIX INTERNATIONAL CO., LTD., Hsinchu (TW)

(72) Inventors: Po-Hao TSENG, Taichung City (TW); Yu-Hsuan LIN, Taichung City (TW); Feng-Min LEE, Hsinchu City (TW); Yung-Chun LI, New Taipei City (TW)

(21) Appl. No.: 17/583,254

(22) Filed: Jan. 25, 2022

(51) Int. Cl. G11C 7/06; G11C 7/14; G11C 15/04; G11C 16/34; G06V 40/16

(52) U.S. Cl. CPC G11C 7/067; G11C 7/14; G11C 15/04; G11C 16/34; G06V 40/172

(57) ABSTRACT

The application provides a content addressable memory (CAM) memory device and a method for searching and comparing data thereof. The CAM memory device comprises: a plurality of CAM memory strings; and a sensing amplifier circuit coupled to the CAM memory strings; wherein in data searching, a search data is compared with a storage data stored in the CAM memory strings, the CAM memory strings generate a plurality of memory string currents, the sensing amplifier circuit senses the memory string currents to generate a plurality of sensing results: based on the sensing results, a match degree between the search data and the storage data is determined as one of the follows: all-matched, partially-matched and all-mismatched.

### BACKGROUND OF THE INVENTION

### Field of the Invention

The invention relates in general to a content addressable memory (CAM) memory device and a method for searching and comparing data thereof, and more particularly to a CAM memory device and a method for searching and comparing data thereof, which are capable of implementing in-memory approximate searching.

### Description of the Related Art

Along with the booming growth in big data and artificial intelligence (AI) hardware accelerator, data search and data comparison have become essential functions. The existing ternary content addressable memory (TCAM) can be configured to implement highly parallel searching. Conventional TCAM is normally formed by static random access memory (SRAM), and therefore has low memory density and requires high access power. Recently, a non-volatile memory array based on TCAM has been provided to save power consumption through dense memory density.

In comparison to the TCAM based on SRAM having 16 transistors (16T), recently a resistive random access memory (RRAM)-based TCAM having 2-transistor and 2-resistor (2T2R) structure has been provided to reduce cell area. Also, standby power consumption can be reduced through the non-volatile RRAM-based TCAM, However, the existing non-volatile TCAM is difficult to distinguish an all-match state and a 1-bit-mismatch state, That is, the existing non-volatile TCAM is not capable of implementing in-memory approximate searching.

Therefore, it has become a prominent task for the industries to provide a CAM memory device and a method for searching and comparing data thereof, which are capable of implementing in-memory approximate searching,

### SUMMARY OF THE INVENTION

According to one embodiment of the present invention, a CAM device is provided. The CAM memory device comprises: a plurality of CAM memory strings; and a sensing amplifier circuit coupled to the CAM memory strings; wherein in data searching, a search data is compared with a storage data stored in the CAM memory strings, the CAM memory strings generate a plurality of memory string currents, the sensing amplifier circuit senses the memory string currents to generate a plurality of sensing results; based on the sensing results, a match degree between the search data and the storage data is determined as one of the follows: all-matched, partially-matched and all-mismatched.

According to an alternate embodiment of the present invention, a method for searching and comparing data of a CAM device is provided. The method includes; storing a storage data in a plurality of CAM memory strings; performing data searching on the CAM memory strings by a search data; sensing a plurality of memory string currents generated from the CAM memory strings to generate a plurality of sensing results; and based on the sensing results, determining a match degree between the search data and the storage data as one of the follows; all-matched, partially-matched and all-mismatched.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of a CAM cell according to a first embodiment of the present application,

FIG. 2 shows a relationship diagram between the search voltage and the cell current in the first embodiment of the application.

FIG. 3 shows a circuit diagram of a CAM memory device according to a second embodiment of the application.

FIG. 4A and FIG. 4B show a circuit diagram of a CAM memory device according to a third embodiment of the application and a decoding result of a face image.

FIG. 5 sows a circuit diagram according to a CAM memory device according to a fourth embodiment of the application.

FIG. 6 shows a flow chart of a method for searching and comparing data for a CAM memory device according to one embodiment of the application.

### DETAILED DESCRIPTION OF THE INVENTION

Technical terms are used in the specification with reference to generally-known terminologies used in the technology field. For any terms described or defined in the specification, the descriptions and definitions in the specification shall prevail. Each embodiment of the present disclosure has one or more technical features. Given that each embodiment is implementable, a person ordinarily skilled in the art can selectively implement or combine some or all of the technical features of any embodiment of the present disclosure.

One embodiment of the application provides a CAM memory device and a method for searching and comparing data thereof. A search data is applied to a plurality of CAM cells via a plurality of word lines. Storage data is stored in the CAM cells. In data searching or data comparison, in a matched state, a gate overdrive voltage is higher than a threshold voltage and thus the transistor provides a high cell current. On the contrary, in a mismatched state, the gate overdrive voltage is lower than the threshold voltage and thus the transistor provides a low cell current. When the search data is all matched with the storage data, a memory string provides a high memory string current; when the search data is partially matched with the storage data, a memory string provides a middle memory string current; and when the search data is all mismatched with the storage data, a memory string provides a low memory string current. That is, the value of the memory string current depends on the match degree (or the mismatch degree) between the search data and the storage data.

### First Embodiment

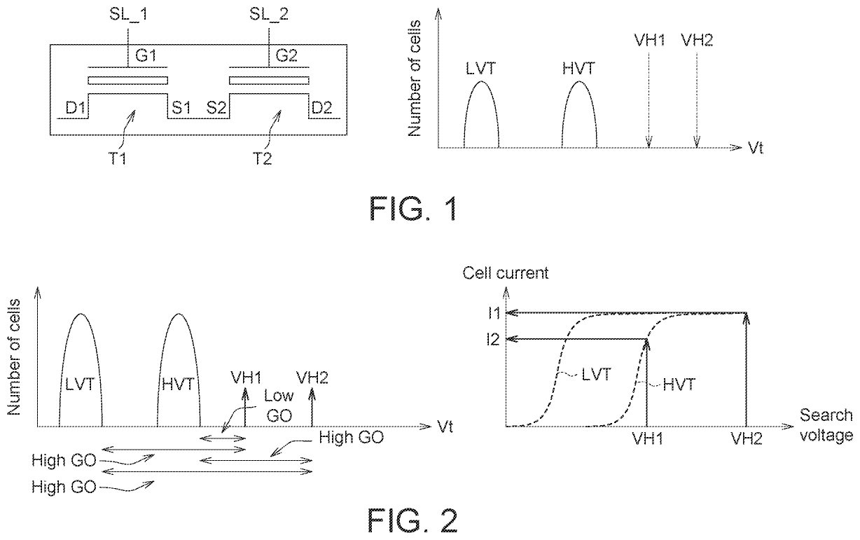

FIG. 1 is a schematic diagram of a CAM cell 100 according to a first embodiment of the present application. As indicated in FIG. 1, the CAM cell 100 according to the first embodiment of the present application may be realized by but is not limited to a single-level CAM capable of storing a single bit.

The CAM cells 100 includes two serial-coupled flash memory cells T1 and T2, wherein the flash memory cells can be realized but is not limited to floating gate memory cells, silicon-oxide-nitride-oxide-silicon (SONOS) memory cells, floating dot memory cells, ferroelectric FET (FeFET) memory cells.

The gate G1 of the flash memory cell T1 is configured to receive a first search voltage The gate G2 of the flash memory cell T2 is configured to receive a second search voltage SL_2. The source S1 of the flash memory cell T1 is electrically connected to the source S2 of the flash memory cell T2. The drain D1 of the flash memory cell T1 and the drain D2 of the flash memory cell T2 are electrically connected to other signal lines (not shown).

Storage data of the CAM cell 100 is determined based on a combination of a plurality of threshold voltages of the flash memory cell T1 and the flash memory cell T2.

FIG. 1 further shows a relationship between the threshold voltage (Vt) and the number of the cells. As shown in FIG. 1, in the first embodiment of the application, a high threshold voltage HVT is for example but not limited by, 3˜4V while a low threshold voltage LVT is for example but not limited by, lower than 0V. Further, the reference search voltages VH1 and VH2 refers to the possible values of the first search voltage SL_1 and/or the second search voltage SL_2. For example but not limited by, the reference search voltages VH1 and VH2 may be 5V and 8V, respectively, i.e. VH1 is smaller than VH2.

Moreover; in the first embodiment of the present application; the threshold voltage of the flash memory cell T1 (also referred as the first threshold voltage); the threshold voltage of the flash memory cell T2 (also referred as the second threshold voltage), the first search voltage SL_1 and the second search voltage SL_2 may be set as follows. The search data is decoded into the first search voltage SL_1 and the second search voltage

| Storage data | 1 | 0 | X (don’t care) | Invalid data |
|---|---|---|---|---|
| the first threshold | HVT | LVT | HVT | LVT |
| voltage | | | | |
| the second threshold | LVT | HVT | HVT | LVT |
| voltage | | | | |

| Search data | 1 | 0 | Wildcard (WC) | Invalid search |
|---|---|---|---|---|
| the first search | VH1 | VH2 | VH2 | VH1 |
| voltage SL_1 | | | | |
| the second search | VH2 | VH1 | VH2 | VH1 |
| voltage SL_2 | | | | |

In the first embodiment of the present application, when the storage data is a first predetermined storage data (1), the first threshold voltage is the high threshold voltage HVT and the second threshold voltage is the low threshold voltage LVT; when the storage data is a second predetermined storage data (0), the first threshold voltage is the low threshold voltage LVT and the second threshold voltage is the high threshold voltage HVT; when the storage data is a third predetermined storage data (X (don't care)), the first threshold voltage and the second threshold voltage are both the high threshold voltage HVT; and when the storage data is a fourth predetermined storage data (that is, invalid data), the first threshold voltage and the second threshold voltage are both the low threshold voltage LVT. That is, in the first embodiment of the present application, the storage data of the CAM cell 100 is based on a combination of the first threshold voltage of the flash memory cell T1 and the second threshold voltage of the flash memory cell T2.

In the first embodiment of the present application, when the search data is a first predetermined search data (0), the first search voltage SL_1 is the first reference search voltage VH1 and the second search voltage SL_2 is the second reference search voltage VH2, wherein the search data represents data to be searched; when the search data is a second predetermined search data (0), the first search voltage SL_1 is the second reference search voltage VH2 and the second search voltage is the first reference search voltage VH1; when the search data is a third predetermined search data (WC), the first search voltage SL_1 and the second search voltage are both the second reference search voltage VH2; and when the search data is a fourth predetermined search data (invalid search), the first search voltage SL_1 and the second search voltage SL_2 are both the first reference search voltage VH1, wherein the first reference search voltage VH1 is lower than the second reference search voltage VH2.

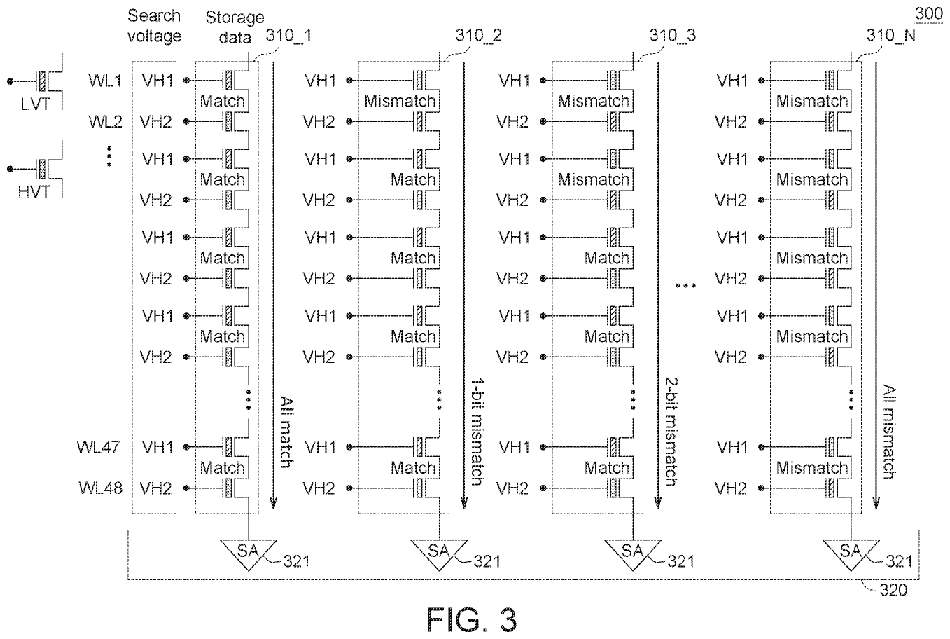

FIG. 2 shows a relationship diagram between the search voltage and the cell current in the first embodiment of the application.

In the first embodiment, the voltage difference between the search voltage (applied to the word line) and the threshold voltage is referred as a gate overdrive voltage (GO). In a matched state, the gate overdrive voltage is higher than a threshold value and the transistor provides a high cell current; and in a mismatched state, the gate overdrive voltage is lower than the threshold value and the transistor provides a low cell current. Taking FIG. 2 as an example, the reference search voltages VH1 and VH2 may be 5V and 8V, respectively, the high reference threshold voltage HVT is for example but not limited by 3˜4V while the low threshold voltage LVT is for example but not limited by, lower than 0V. The gate overdrive voltage between the reference search voltage VH2 (8V) and the high reference threshold voltage HVT (3˜4V) is about 4˜5V, which is a high gate overdrive voltage; the gate overdrive voltage between the reference search voltage VH2 (8V) and the low threshold voltage LVT (lower than 0V) is about higher than 8V, which is a high gate overdrive voltage; the gate overdrive voltage between the reference search voltage VH1 (5V) and the high reference threshold voltage HVT (3˜4V) is about 1˜2V, which is a low gate overdrive voltage; the gate overdrive voltage between the reference search voltage VH1 (5V) and the low threshold voltage LVT (lower than 0V) is about higher than 5V, which is a high gate overdrive voltage.

In details, when the search voltage is the second reference search voltage VH2, no matter the threshold voltage of the transistor is either the low threshold voltage LVT or the high threshold voltage HVT, the gate overdrive voltage of the transistor is higher than the threshold value and thus the transistor provides a high reference cell current (I1). In the case that the search voltage is the first reference search voltage VH1, (1) when the threshold voltage of the transistor is the low threshold voltage LVT, the gate overdrive voltage of the transistor is higher than the threshold value and thus the transistor provides the high reference cell current (I1); and (2) when the threshold voltage of the transistor is the high threshold voltage HVT, the gate overdrive voltage of the transistor is lower than the threshold value and thus the transistor provides the low reference cell current (I2).

In one example, for example but not limited by, when the high threshold voltage HVT is 3˜4V, the low threshold voltage LVT is lower than 0V, the reference search voltages VH1 and VH2 may be 5V and 8V, respectively, the high reference cell current (I1) and the low reference cell current (I2) are 100˜500 nA and 1˜99 nA, respectively.

In one embodiment, the match state between the search data and the storage data is as follows.

| | Search data 1 | Search data 0 | WC | Invalid search |
|---|---|---|---|---|
| Storage data | T1: X | T1: O | T1: O | T1: X |
| 0 | T2: O | T2: O | T2: O | T2: O |
| | Mismatch | Match (high | Match (high | Mismatch |
| | (low | reference cell | reference cell | (low |
| | reference cell | current) | current) | reference cell |
| | current) | | | current) |
| Storage data | T1: O | T1: O | T1: O | T1: O |
| 1 | T2: O | T2: X | T2: O | T2: X |
| | Match (high | Mismatch | Match (high | Mismatch |
| | reference cell | (low | reference cell | (low |
| | current) | reference cell | current) | reference cell |
| | | current) | | current) |
| Storage data | T1: O | T1: O | T1: O | T1: O |
| X | T2: O | T2: O | T2: O | T2: O |
| | Match (high | Match (high | Match (high | Match (high |
| | reference cell | reference cell | reference cell | reference cell |
| | current) | current) | current) | current) |
| Invalid data | T1: X | T1: O | T1: O | T1: X |
| | T2: O | T2: X | T2: O | T2: X |
| | Mismatch | Mismatch | Match (high | Mismatch |
| | (low | (low | reference cell | (low |
| | reference cell | reference cell | current) | reference cell |
| | current) | current) | | current) |

X: non-conduc (low gate overdrive voltage)
O: conduct (high gate overdrive voltage)

Thus, when the search data is logic 1 while the storage data is logic 0, the flash memory cell T1 is not conducted while the flash memory cell T2 is conducted, and the cell current of the CAM cell 100 is the low reference cell current (I2), which means the search result is mismatched. When the search data is logic 0 while the storage data is logic 0, the flash memory cell T1 and the flash memory cell T2 are both conducted, and the cell current of the CAM cell 100 is the high reference cell current (I1), which means the search result is matched,

In searching, when the search data is matched with the storage data, the cell current of the CAM cell 100 is the high reference cell current (I1), which means the search result is matched. When the search data is mismatched with the storable data, the cell current of the CAM cell 100 is the low reference cell current (I2), which means the search result is mismatched.

When the search data is wildcard (WC), no matter what value of the storage data is, the cell current of the CAM cell 100 is the high reference cell current (I1), which means the search result is matched. When the search data is invalid search, no matter the storage data is logic 1 or logic 0 or invalid data, the cell current of the CAM cell 100 is the low reference cell current (I2), which means the search result is mismatched.

When the storage data is X (don't care), no matter what value of the search data is, the cell current of the CAM cell 100 is the high reference cell current (I1), which means the search result is matched. When the storage data is invalid data, no matter the search data is logic 1, logic 0 or invalid search, the cell current of the CAM cell 100 is the low eference cell current (I2), which means the search result is mismatched.

### Second Embodiment

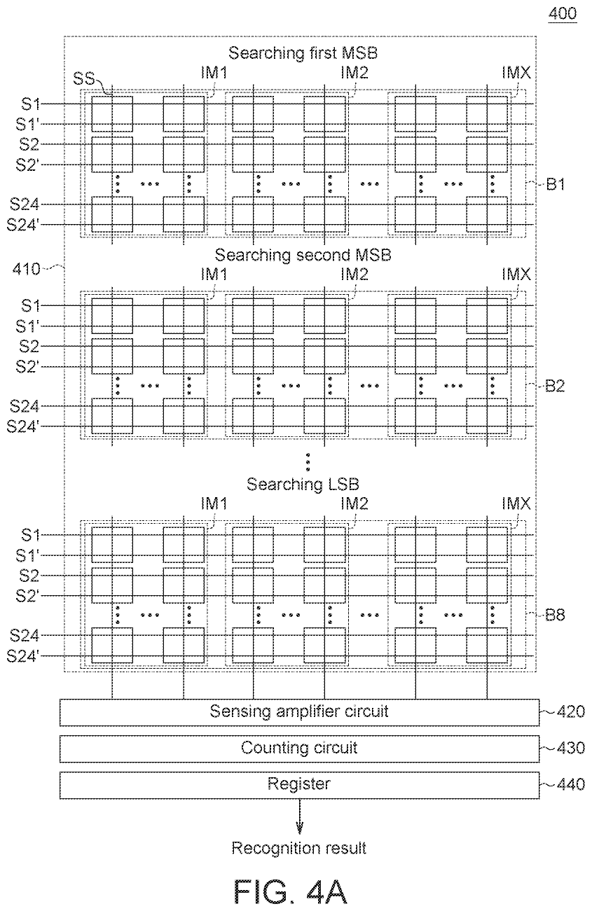

FIG. 3 shows a circuit diagram of a CAM memory device 300 according to a second embodiment of the application. As shown in FIG. 3, the CAM memory device 300 according to the second embodiment of the application includes a plurality of memory strings 310_1˜310_N, a sensing amplifier circuit 320 and a plurality of word lines (WL1˜WL48 in FIG. 3, but the application is not limited by this). The sensing amplifier circuit 320 includes a plurality of sensing amplifiers 321 and each of the sensing amplifiers 321 is coupled to one among the memory strings 310_1˜310_N.

Each of the memory strings 310_1˜310_N includes a plurality of cascaded CAM cells (for example, the CAM cell 100 in FIG. 1).

In-memory approximate searching in the second embodiment of the application is explained.

For simplicity, storage data of the CAM cells of the memory strings 310_1˜310_N are as follows. All CAM cells of the memory string 310_1 store logic 1. In the memory string 310_2, one CAM cell stores logic 0 while the other CAM cells store logic 1. In the memory string 310_3, two CAM cells store logic 0 while the other CAM cells store logic 1. All CAM cells of the memory string 310_N store logic 0.

Further, twenty-four search voltage sets are applied to the memory strings 310_1˜310_N via the word lines WL1˜WL48 for approximate searching. For simplicity, the twenty-four search voltage sets are set as search data 1.

After search, because all CAM cells of the memory string 310_1 store logic 1, all CAM cells of the memory string 310_1 provide the high reference cell currents (I1), which means that the memory string 310_1 provides a memory string having a current value of 24*I1. In one embodiment, the memory string 310_1 is defined as all-match state. That is, the search results of all CAM cells of the memory string 310_1 are all matched.

Similarly, after search, because in the memory string 310_2, one CAM cell stores logic 0 while the other CAM cells store logic 1 the CAM cells of the memory string 310_2 provide twenty-three high reference cell currents (I1) and one low reference cell current 02), which means that the memory string 310_2 provides a memory string having a current value of 23*I1+1*I2. In one embodiment, the memory string 310_2 is defined as 1-bit mismatch state. That is, one CAM cell of the memory string 310_2 has a mismatch search result while the other CAM cells of the memory string 310_2 have match search results.

Similarly, the CAM cells of the memory string 310_2 provide twenty-two high reference cell currents (I1) and two low reference cell currents (I2), which means that the memory string 310_3 provides a memory string having a current value of 22*I1+2*I2, In one embodiment, the memory string 310_3 is defined as 2-bit mismatch state. That is, two CAM cells of the memory string 310_3 have mismatch search results while the other CAM cells of the memory string 310_3 have match search results.

Similarly, after search, all CAM cells of the memory string 310_N provide twenty-four low reference cell currents (I2), which means that the memory string 310_N provides a memory string having a current value of 24*I2, In one embodiment, the memory string 310_N is defined as all mismatch state, That is, the search results of all CAM cells of the memory string 310_N are all mismatched.

For simplicity, the search results of the memory strings are classified into three types: the all-match state (for example the memory string 310_1), the partial-match state (for example the memory strings 310_2˜310_(N-1)) and the all-mismatch state (for example the memory string 310_N).

Further, in the second embodiment of the application, by tuning the sensing time of the sensing amplifiers 321 to sense different memory string currents, to differentiate the all-match state, the partial-match state and the all-mismatch state. For example, when the sensing time of the sensing amplifier 321 is tuned to be longer, the sensing amplifier 321 is capable sensing small memory string current; and vice versa.

Thus, taken FIG. 3 as an example, if the sensing time of the sensing amplifier 321 is tuned to sense the memory string current having a value of (22*I1+2*I2), then the three sensing amplifiers 321 coupled to the memory strings 310_1˜310_3 sense the memory string currents from the memory strings 310_1˜310_3 and the other sensing amplifiers 321 do not sense the memory string currents from the memory strings 310_4˜310_N (because the memory string currents from the memory strings 310_4˜310_N are too small to be sensed).

The three sensing amplifiers 321 coupled to the memory strings 310_1˜310_3 output digital signal 1 (which means the match state between the search data and the storage data) while the other sensing amplifiers 321 output digital signal 0.

That is, when the sensing amplifier 321 senses the memory string current from the memory string, the sensing amplifier 321 outputs digital signal 1; and when the sensing amplifier 321 does not sense the memory string current from the memory string, the sensing amplifier 321 outputs digital signal 0.

### Third Embodiment

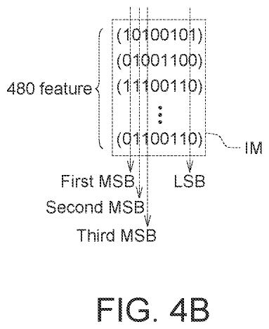

FIG. 4A and FIG. 4B show a circuit diagram of a CAM memory device according to a third embodiment of the application and a decoding result of a face image. The CAM memory device 400 according to the third embodiment of the application includes: a memory array 410, a sensing amplifier circuit 420, a counting circuit 430 and a register 440.

The memory array 410 includes a plurality of memory strings SS.

The sensing amplifier circuit 420 is coupled to the memory array 410. The sensing amplifier circuit 420 includes a plurality of sensing amplifiers (not shown) respectively coupled to the memory strings. The sensing amplifier circuit 420 senses a plurality of memory string currents from the memory strings SS to generate a plurality of sensing results.

The counting circuit 430 is coupled to the sensing amplifier circuit 420 to count the sensing results for generating a plurality of matching scores. In response to the sensing result indicating higher memory string current, the matching score is higher and vice versa.

The register 440 is coupled to the counting circuit 430 for storing the matching scores from the counting circuit 430.

Application of the memory device 400 of the third embodiment in face image recognition is described to understand hove to implement the in-memory approximate search by the memory device 400 of the third embodiment.

For simplicity, a face image IM is decoded into 480 features. Each of the features has 8-bit resolution, i.e. from a first MSB (most significant bit), a second MSB, . . . , to an LSB (least significant bit), but the application is not limited by this. That is, the face image IM includes 480 first MSBs, 480 second MSBs, 480 LSBs. That is, the storage data includes 480 first MSBs, 480 second MSBs, . . . , 480 LSBs.

For face image recognition, a plurality of reference face images IM1˜IMX (X being a positive integer) are stored in the memory array 410. For example, the respective 480 first MSBs of the reference face images IM1˜IMX are stored in a block B1 of the memory array 410, the respective 480 second MSBs of the reference face images IM1˜IMX are stored in a block B2 of the memory array 410 . . . , and the respective 480 LSBs of the reference face images IM1˜IMX are stored in a block B8 of the memory array 410.

In face image recognition, the face image under search is decoded into a plurality of search voltages S1, S1′, S2, S2′, . . . , S24 and S24′ to perform approximate search on the reference face images IM1˜IMX.

Respective matching scores of the reference face images IM1˜IMX are counted by the counting circuit 430 and stored in the register 440. Based on the matching scores, a target reference face image, which is corresponding to a highest matching score, among the reference face images IM1˜IMX is determined as the same or most similar to the face image under search.

### Fourth Embodiment

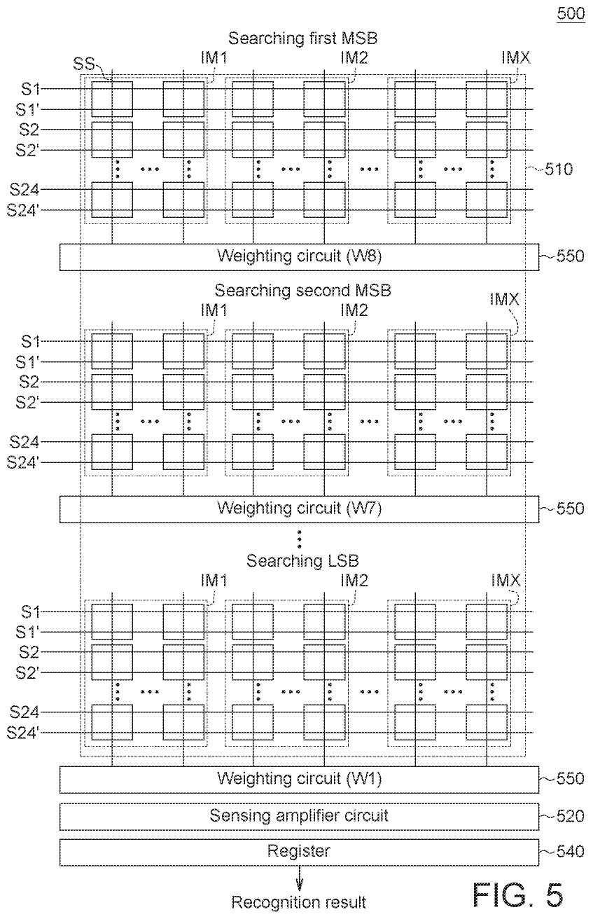

FIG. 5 sows a circuit diagram according to a CAM memory device according to a fourth embodiment of the application. As shown in FIG. 5, the CAM memory device according to the fourth embodiment of the application includes a memory array 510, a sensing amplifier circuit 520, a register 540 and a plurality of weighting circuits 550,

The weighting circuits 550 are coupled to the memory strings of the memory array 510. The weighting circuits 550 assigns different weights to the memory string currents generated from the memory strings.

In face image recognition, MSB of the features dominate image characteristics. Thus, in the fourth embodiment of the application, the weighting circuits 550 are introduced to increase search accuracy. The memory string current generated by searching the first MSBs is assigned by a highest weight W8; the memory string current generated by searching the second MSBs is assigned by a second highest weight W7; . . . ; and the memory string current generated by searching the LSBs is assigned by a lowest weight W1, wherein W8>W7> . . . >W1.

In face recognition, the face image under search is decoded into the search voltages S1, St, S2, S2′, . . . , S24, S24′ to perform approximate search on the reference face images IM1˜IMX.

The weighted memory string currents generated by searching the reference face images IM1˜IMX are summed and stored in the register 540. Based on the summed memory string currents, a target reference face image, which is corresponding to a highest summed string current, among the reference face images IM1˜IMX is determined as the same or most similar to the face image under search.

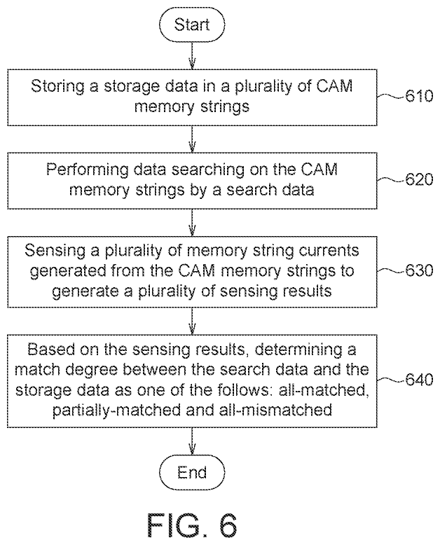

FIG. 6 shows a flow chart of a method for searching and comparing data for a CAM memory device according to one embodiment of the application. The data search and comparing method for the CAM memory device comprises: storing a storage data in a plurality of CAM memory strings (610); performing data searching on the CAM memory strings by a search data (620); sensing a plurality of memory string currents generated from the CAM memory strings to generate a plurality of sensing results (630); and based on the sensing results, determining a match degree between the search data and the storage data as one of the follows: all-matched, partially-matched and all-mismatched (640).

In above embodiments of the present application, the CAM memory device can be realized as a two-dimensional (2D) flash memory architecture or a three-dimensional (3D) flash memory architecture, and is still within the spirit of the present application.

In above embodiments of the present application, in performing in-memory approximate search, by assigning different to the memory string currents by searching the MSB and the LSB, the match speed and the match accuracy are improved.

In one embodiment of the application, in performing in-memory approximate search, data search and data comparison are completed during one read cycle. Accompanied by high storage density of the CAM memory device, the in-memory approximate search may be applicable in different field, for example but not limited by, Big-data searching, AI (artificial intelligence) hardware accelerator/classifier, Approximate Computing, Associative memory, Solid-state drive (SSD) data management, deoxyribonucleic acid (DNA) matching, Data filter and so on.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A content addressable memory (CAM) memory device, comprising:
a plurality of CAM memory strings; and
a sensing amplifier circuit coupled to the CAM memory strings;
wherein
in data searching, a search data is compared with a storage data stored in the CAM memory strings, the CAM memory strings generate a plurality of memory string currents, the sensing amplifier circuit senses the memory string currents to generate a plurality of sensing results;
based on the sensing results, a match degree between the search data and the storage data is determined as one of the follows: all-matched, partially-matched and all-mismatched.

2. The CAM memory device according to claim 1, wherein
when the search data is all-matched with the storage data, the sensing amplifier circuit senses a first memory string current;
when the search data is partially-matched with the storage data, the sensing amplifier circuit senses a second memory string current; and
when the search data is all-mismatched with the storage data, the sensing amplifier circuit senses a third memory string current;
the first memory string current is higher than the second memory string current; and the second memory string current is higher than the third memory string current.

3. The CAM memory device according to claim 1, wherein
the CAM memory strings include a plurality of CAM cells;
each of the CAM cells includes a first memory cell and a second memory cell in cascade;
when a first predetermined storage data is stored in the CAM cell, a first threshold voltage of the first memory cell is a first reference threshold voltage and a second threshold voltage of the second memory cell is a second reference threshold voltage;
when a second predetermined storage data is stored in the CAM cell, the first threshold voltage of the first memory cell is the second reference threshold voltage and the second threshold voltage of the second memory cell is the first reference threshold voltage;
when a third predetermined storage data is stored in the CAM cell, the first threshold voltage of the first memory cell and the second threshold voltage of the second memory cell are both the first reference threshold voltage; and
when a fourth predetermined storage data is stored in the CAM cell, the first threshold voltage of the first memory cell and the second threshold voltage of the second memory cell are both the second reference threshold voltage.

4. The CAM memory device according to claim 3, wherein
when the search data is a first predetermined search data, a first search voltage applied to the first memory cell is a first reference search voltage and a second search voltage applied to the second memory cell is a second reference search voltage;
when the search data is a second predetermined search data, the first search voltage applied to the first memory cell is the second reference search voltage and the second search voltage applied to the second memory cell is the first reference search voltage;
when the search data is a third predetermined search data, the first search voltage applied to the first memory cell and the second search voltage applied to the second memory cell are both the second reference search voltage; and
when the search data is a fourth predetermined search data, the first search voltage applied to the first memory cell and the second search voltage applied to the second memory cell are both the first reference search voltage,
wherein the first reference search voltage is lower than the second reference search voltage.

5. The CAM memory device according to claim 1, wherein the sensing amplifier circuit includes a plurality of sensing amplifiers one-to-one coupled to the CAM memory strings,
wherein
when the sensing amplifier senses the memory string current provided from the CAM memory string, the sensing amplifier outputs a first logic digital signal; and
when the sensing amplifier fails to sense the memory string current provided from the CAM memory string, the sensing amplifier outputs a second logic digital signal.

6. The CAM memory device according to claim 2, further including:
a counting circuit coupled to the sensing amplifier circuit, for counting the sensing results to generate a plurality of matching scores; and
a register coupled to the counting circuit for storing the matching scores from the counting circuit,
wherein
when the sensing amplifier circuit senses the first memory string current, the counting circuit generates a first matching score;
when the sensing amplifier circuit senses the second memory string current, the counting circuit generates a second matching score;
when the sensing amplifier circuit senses the third memory string current, the counting circuit generates a third matching score;
the first matching score is higher than the second matching score, the second matching score is higher than the third matching score.

7. The CAM memory device according to claim 1, further including:
a plurality of weighting circuit coupled to the CAM memory strings for assigning different weights to the memory string currents generated from the CAM memory strings;
when the storage data includes a MSB and a LSB, the memory string current corresponding to searching the MSB is assigned by a first weight, the memory string current corresponding to searching the LSB is assigned by a second weight smaller than the first weight.

8. The CAM memory device according to claim 6, wherein
a plurality of reference face images are stored in the CAM memory strings;
in face image recognition, a face image under search is decoded into a plurality of search voltages to perform approximate search on the reference face images;
respective matching scores of the reference face images are counted by the counting circuit and stored in the register;
based on the matching scores, a target reference face image, corresponding to a highest matching score of the matching scores, among the reference face images is determined to be the same or most similar to the face image under search.

9. A data search and comparing method for a content addressable memory (CAM) memory device, the method comprising:
storing a storage data in a plurality of CAM memory strings;
performing data searching on the CAM memory strings by a search data;
sensing a plurality of memory string currents generated from the CAM memory strings to generate a plurality of sensing results; and
based on the sensing results, determining a match degree between the search data and the storage data as one of the follows: all-matched, partially-matched and all-mismatched.

10. The data search and comparing method for the CAM memory device according to claim 9, wherein
when the search data is aft-matched with the storage data, a first memory string current is sensed;
when the search data is partially-matched with the storage data, a second memory string current is sensed; and
when the search data is all-mismatched with the storage data, a third memory string current is sensed;
the first memory string current is higher than the second memory string current; and the second memory string current is higher than the third memory string current.

11. The data search and comparing method for the CAM memory device according to claim 9, wherein
the CAM memory strings include a plurality of CAM cells;
each of the CAM cells includes a first memory cell and a second memory cell in cascade;
when a first predetermined storage data is stored in the CAM cell, a first threshold voltage of the first memory cell is a first reference threshold voltage and a second threshold voltage of the second memory cell is a second reference threshold voltage;
when a second predetermined storage data is stored in the CAM cell, the first threshold voltage of the first memory cell is the second reference threshold voltage and the second threshold voltage of the second memory cell is the first reference threshold voltage;
when a third predetermined storage data is stored in the CAM cell, the first threshold voltage of the first memory cell and the second threshold voltage of the second memory cell are both the first reference threshold voltage; and
when a fourth predetermined storage data is stored in the CAM cell, the first threshold voltage of the first memory cell and the second threshold voltage of the second memory cell are both the second reference threshold voltage.

12. The data search and comparing method for the CAM me device according to claim 11, wherein
when the search data is a first predetermined search data, a first search voltage applied to the first memory cell is a first reference search voltage and a second search voltage applied to the second memory cell is a second reference search voltage;
when the search data is a second predetermined search data, the first search voltage applied to the first memory cell is the second reference search voltage and the second search voltage applied to the second memory cell is the first reference search voltage;
when the search data is a third predetermined search data, the first search voltage applied to the first memory cell and the second search voltage applied to the second memory cell are both the second reference search voltage; and
when the search data is a fourth predetermined search data, the first search voltage applied to the first memory cell and the second search voltage applied to the second memory cell are both the first reference search voltage,
wherein the first reference search voltage is lower than the second reference search voltage.

13. The data search and comparing method for the CAM me or device according to claim 9, wherein
when the memory string current provided from the CAM memory string is sensed, a first logic digital signal s output; and
when it is failed to sense the memory string current provided from the CAM memory string, a second logic digital signal is output.

14. The data search and comparing method for the CAM memory device according to claim 10, further including:
counting the sensing results to generate a plurality of matching scores; and
storing the matching scores,
wherein
when the first memory string current is sensed, a first matching score is generated;
when the second memory string current is sensed, a second matching score is generated;
when the third memory string current is sensed, a third matching score is generated;
the first matching score is higher than the second matching score, the second matching score is higher than the third matching score.

15. The data search and comparing method for the CAM memory device according to claim 9, wherein
when the storage data includes a MSB and a LSB, the memory string current corresponding to searching the MSB is assigned by a first weight, the memory string current corresponding to searching the LSB is assigned by a second weight smaller than the first weight.

16. The data search and comparing method for the CAM memory device according to claim 14, wherein
a plurality of reference face images are stored in the CAM memory strings;
in face image recognition, a face image under search is decoded into a plurality of search voltages to perform approximate search on the reference face images;
respective matching scores of the reference face images are counted; and
based on the matching scores, a target reference face image, corresponding to a highest matching score of the matching scores, among the reference face images is determined to be the same or most similar to the face image under search.
